(19) United States
(12) Patent Application Publication
(10) Pub. No.: US 2013/0070514 A1
(43) Pub. Date: Mar. 21, 2013

(54) INTEGRATED CIRCUIT WITH ON-DIE DISTRIBUTED PROGRAMMABLE PASSIVE VARIABLE RESISTANCE FUSE ARRAY AND METHOD OF MAKING SAME

(71) Applicants: Donald R. Weiss, Fort Collins, CO (US); John J. Wuu, Fort Collins, CO (US)

(72) Inventors: Donald R. Weiss, Fort Collins, CO (US); John J. Wuu, Fort Collins, CO (US)

(73) Assignee: ADVANCED MICRO DEVICES, INC., Sunnyvale, CA (US)

(21) Appl. No.: 13/616,021

(22) Filed: Sep. 14, 2012

Related U.S. Application Data
(60) Provisional application No. 61/535,728, filed on Sep. 16, 2011.

(51) Int. Cl. H01L 45/00; G11C 11/00; H01L 21/02

(52) U.S. Cl. 365/148; 257/5; 438/382; 257/E45.002; 257/E21.004

(57) ABSTRACT

An integrated circuit employs a plurality of functional blocks, such as but not limited to, processors (e.g., cores), and an on-die distributed programmable passive variable resistance memory array configured to provide configuration information for each of the plurality of functional blocks. A corresponding sub-portion of the on-die distributed programmable passive variable resistance memory array is fabricated in layers above each respective plurality of functional blocks. The on-die distributed programmable passive variable resistance memory array is used as either non-volatile prepackage configuration information store, or a non-volatile post-package configuration information store that may allow dynamic changing of hardware configuration of the functional blocks both during normal operation and prior to die packaging. A method for making the same is also disclosed.

### RELATED APPLICATIONS

This application claims priority to Provisional Application Ser. No. 61/535,728, filed on Sep. 16, 2011, having inventors Don R. Weiss et al., titled “AN INTEGRATED CIRCUIT WITH ON-DIE DISTRIBUTED PROGRAMMABLE PASSIVE VARIABLE RESISTANCE FUSE ARRAY AND METHOD OF MAKING SAME”, and is incorporated herein by reference.

### BACKGROUND OF THE INVENTION

The disclosure relates generally to integrated circuits that employ integrated fuses and more particularly to integrated circuits that employ non-volatile memory used to provide hardware configuration information.

Integrated circuits are known to employ on-die electrically programmed fuses that are write once fuses that may require silicon or metal that is burned to an open circuit by applying a high programming voltage, typically higher than the nominal operating voltage of the integrated circuit. Programming transistors are used to select the fuse and burn the fuse open in an open circuit thereby fixedly setting register bits or other configuration aspects that are used to configure various hardware circuits in functional blocks on the integrated circuit. Because of the large currents required to program the fuses, the on-die programming typically requires an external programming voltage that is higher than the normal operating voltage of the processor. The on-die fuses are single or write once only fuses and are used in prepackaging configuration to configure the die before it is packaged. Also, a sensing circuit senses whether a fuse is a closed or open circuit. The sensing logic can be fairly complex to reliably read the differences between an unprogrammed and a programmed fuse. Such fuses also take up large areas of an integrated circuit which can impact the cost and the complexity of the dies and can impact yield and hence are typically a limited resource.

FIG. 1 illustrates an example of integrated circuit die or chip that employs the aforementioned one time writable fuse block 100 on the die 102 which in this example is a processor die having a plurality of functional blocks such as CPU cores 104, 106, 108 and 110. Control logic 112 may, for example, have the sense circuitry to read the fuse setting in the one time writable fuses in the fuse block 100. Writing (blowing) the fuse may be done using an off-chip voltage source and selection logic in the control logic 112 as known in the art. In addition, the fuse block 100 is typically located laterally adjacent to the functional blocks which adds to the overall physical area of the chip (i.e., die). Off-die non-volatile configuration memory 114 is also employed that may be, for example, in its own integrated circuit package 116 this is in the integrated circuit package but off-die. The non-volatile configuration memory 114 such as one time programmable ROM (PROM) may also be placed on an integrated circuit board 120 as shown by non-volatile memory 122. As such, the non-volatile configuration memory 114 provides package level configuration information 126 to control logic 112 whereas non-volatile configuration memory 122 provides post-package configuration information 128 for the chip 102 such as system level configuration information to be used by the BIOS or other suitable system level configuration mechanism.

The on-die programmable fuse structure employing fuse block 100 is used typically to provide fuse capability before packaging. Examples of prepackage configuration information provided by the on-die fuse block 100 may be, for example, setting the operating frequency and/or clock frequency of the various CPU cores. The on-die fuses are typically on the edge of the die in relatively small number of places (e.g., one or two) and high power lines or traces are required to be connected to the on-die fuse circuits to provide the adequate programming voltage as noted above. Circuitry in the controller 112 to read and write the on-die fuses requires an inordinate amount of real estate. In addition, the fuses are typically not very close to the functional block for which they are used thereby also limiting the location of the fuses and wiring adjacent to the corresponding functional block.

The off chip package level configuration information in non-volatile memory 114 and off package non-volatile memory 122 may be reprogrammable such as flash memory but such memory can be expensive and is not typically on-die and hence may be more accessible to hackers.

A need exists for an improved configuration structure that overcomes one or more of the above drawbacks.

### BRIEF DESCRIPTION OF THE DRAWINGS

The invention will be more readily understood in view of the following description when accompanied by the below figures and wherein like reference numerals represent like elements, wherein:

FIG. 1 is a prior art block diagram illustrating one example of one time programmable on-die fuses and reprogrammable off-die and off package configuration memories as known in the art;

FIG. 2 is a block diagram illustrating one example of an integrated circuit that employs a sub-portion of an on-die distributed programmable passive variable resistance memory array in accordance with one example set forth in the disclosure;

FIG. 3 is a block diagram illustrating one example of an integrated circuit employing a plurality of functional blocks and an on-die distributed programmable passive variable resistance memory array in accordance with one example set forth in the disclosure;

FIG. 4 is a cross-sectional view illustrating one example of an integrated circuit incorporating an on-die distributed programmable passive variable resistance memory array in accordance with one example set forth in the disclosure;

FIG. 5 is a flowchart illustrating one example of a method for making an integrated circuit in accordance with one example set forth in the disclosure; and

FIG. 6 is one example of a device employing a plurality of circuit packages that employ on-die distributed programmable passive variable resistance memory arrays in accordance with one example of the disclosure.

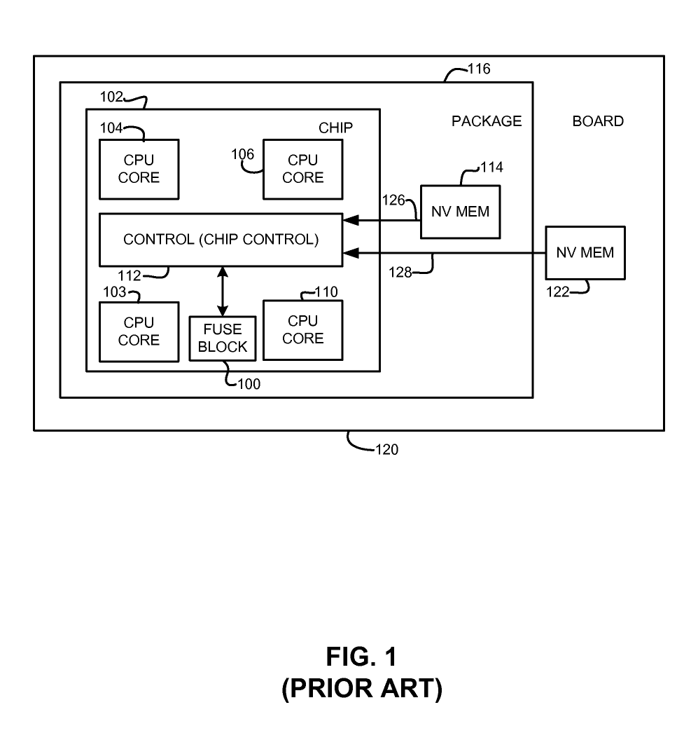

### DETAILED DESCRIPTION OF THE PREFERRED EMBODIMENTS

Briefly, an integrated circuit employs a plurality of functional blocks, such as but not limited to, processors (e.g., cores), and an on-die distributed programmable passive variable resistance memory array configured to provide configuration information for each of the plurality of functional blocks. A corresponding sub-portion of the on-die distributed programmable passive variable resistance memory array is fabricated in layers above each respective plurality of functional blocks. The on-die distributed programmable passive variable resistance memory array is used as either non-volatile prepackage configuration information store, or a non-volatile post-package configuration information store that may allow dynamic changing of hardware configuration of the functional blocks both during normal operation and non-normal operation (e.g., prior to die packaging). Employing a distributed programmable passive variable resistance memory array wherein sub-portions are located in layers above each respective plurality of functional blocks can result in a smaller integrated circuit design and can allow a larger number of fuse type operations or other hardware configuration operations to be facilitated using an improved design. A method for making the same is also disclosed.

In one example, the integrated circuit includes program logic that programs the configuration information in the on-die distributed programmable passive variable resistance memory array during prepackage operation of the plurality of functional blocks and post-package or normal operation of the functional blocks. In one example, the program logic that programs the on-die distributed programmable passive variable resistance memory array uses a normal operating voltage of the integrated circuit, as opposed to using a higher voltage or higher current external source that some on-die structures is used. In one example, the integrated circuit also includes control logic that reads the configuration information stored in the respective sub-portions of each of the on-die distributed programmable passive variable resistance memory array to control each respective functional block as dictated by the configuration information (e.g., bits). The control logic, in response to the respective configuration information for a given functional block may perform many operations such as controlling the operating speed of one or more functional blocks, control selection of a redundant functional block to replace another functional block, control a supply voltage level for a functional block to be set at different settings, control a security level of a functional block, control selection of different combinations of functional blocks based on, for example, pay for performance criteria, control use of different functional blocks in the integrated circuit for different end users, change the security level of one or more functional blocks, or for any other suitable purpose.

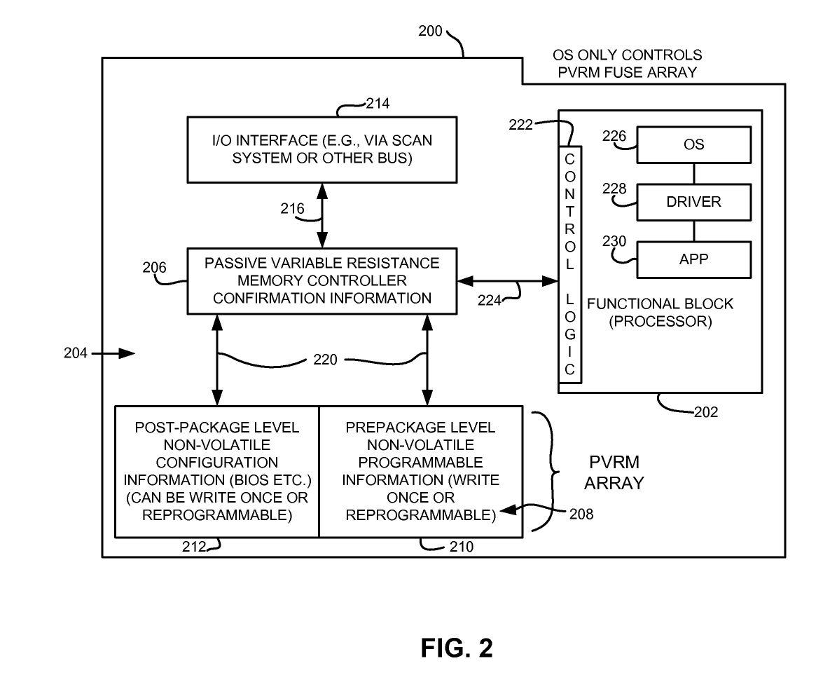

Referring to FIG. 2, a portion of an integrated circuit 200 which in this example is a die, includes a functional block 202, such as a processor core, graphics processor core, arithmetic logic unit (ALU), or any suitable functional block that may be fabricated on an integrated circuit die. In this example, the die 200 includes a sub-portion 204 of an on-die distributed programmable passive variable resistance memory array. A passive variable resistance memory controller 206 controls reads and writes to a programmable passive variable resistance memory 208 which forms part of the array and which may contain prepackage level configuration information 210 that may be used during a prepackage configuration mode to configure the functional block 202. The programmable passive variable resistance memory 208 in this example also includes post package level configuration information 212 such as hardware configuration information used by a BIOS or other suitable post package level configuration mechanism. Examples of prepackage configuration operations include cache repair (i.e. redundant cache mapping) and local clock skew adjustment. Examples of post-configuration operations include selecting a number of cores on a die to enable, selecting an amount of cache to enable and selecting a maximum frequency to enable.

Data to be written to the programmable passive variable resistance memory 208 during a prepackage or chip level configuration operation may be done through an input/output interface 214 as known in the art which may be, for example, an integrated circuit scan infrastructure, dedicated input/output logic structure or any other suitable interface. In this example, link 216 which may be any suitable communication link allows communication of configuration information to/from the passive variable resistance memory controller 206. Accordingly, during a test operation for example, a test computer may be connected to I/O interface 214 to suitably read or write configuration information 210 by sending read or write information to the passive variable resistance memory controller 206. The passive variable resistance memory controller 222 may be any suitable passive variable resistance memory control logic as further described below that can effect reads and writes to programmable passive variable resistance memory, such as a memristor memory or any other suitable passive variable resistance memory. As shown, the read and write information is communicated via one or more links 220.

The functional block 202, in this example, includes control logic 222 used to respond to the configuration information obtained from the passive variable resistance memory 208. The control logic 222 is responsive to the stored prepackage or post-package level configuration information 210 or 212 to control various aspects of the functional block 202 as further described below. The controller 222, in addition to reading configuration information from the passive variable resistance memory 208, may also write configuration information to the passive variable resistance memory 208 via a suitable link 224 which is connected to the passive variable resistance controller 206. The control logic 222 may be any suitable state machine, suitably controlled microcontroller or any other suitable logic.

In one example, where the functional block 202 is a processor, the processor may include memory or be connected to memory that stores an operating system 226, drivers 228, and applications 230 that are executed by the processor. It will be recognized that the functional block may perform any suitable function on an integrated circuit die. Although a sub-portion of an on-die distributed passive variable resistance memory array is shown in FIG. 2, it will be recognized that the blocks may be replicated so that a plurality of functional blocks are located on a die in addition to multiple sub-portions of the on-die distributed programmable passive variable resistance memory array. The combination of sub-portions forms the array.

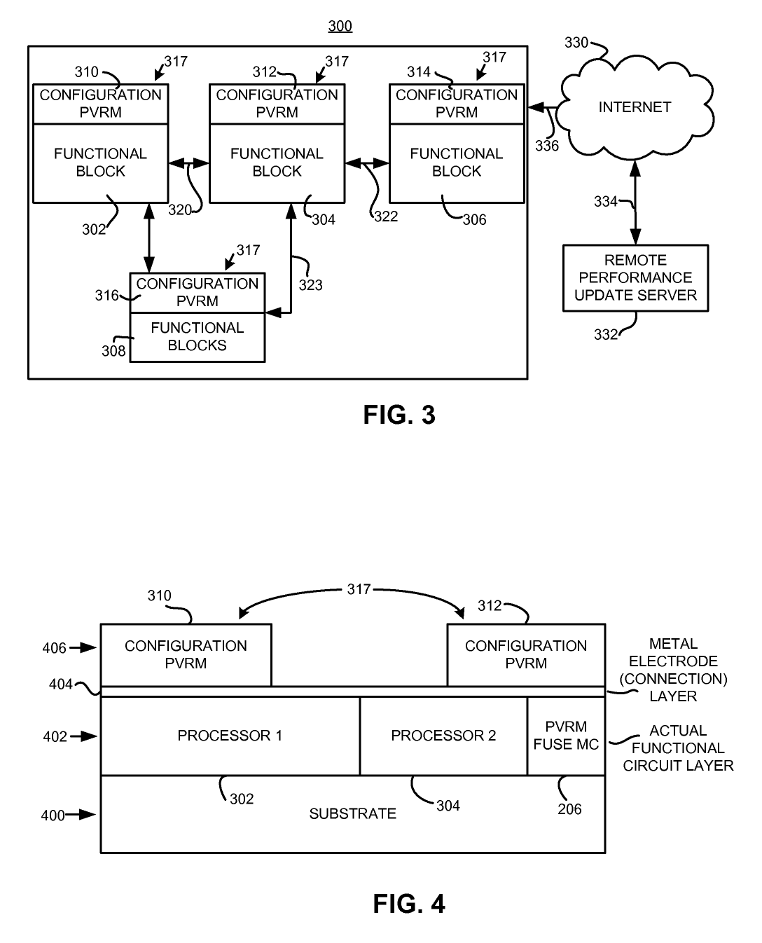

For example, FIG. 3 illustrates one example of the integrated circuit 200 shown to be a die that includes a plurality of functional blocks 302, 304, 306 and 308 and for purposes of illustration only and not limitation, functional blocks will be referred to as processor cores on a die 300. Each of the functional blocks has an associated sub-portion of on-die distributed passive variable resistance memory 310, 312, 314 and 316 respectively, that in this example are shown to physically lie above each respective functional block. The multiple sub-portions form an array of passive variable resistance memory.

The plurality of functional blocks in this example are interconnected through logic (as known in the art and not shown) whose interconnection is shown generally through links 320, 322 and 323 so that all four processor cores may communicate with one another either directly or through a hub or any other suitable structure. In this example, a quad core configuration is shown. However, any suitable functional block or any suitable number of processing cores may be employed. Die 300 may be suitably packaged into an integrated circuit package having suitable pins or content pads for soldering to a circuit board and may be placed in a device including, but not limited to, a smart phone, printer, HDTV, server, or may be employed in any other suitable device. In this example, the die 300 is employed in a wireless device such as a smart phone that wirelessly communicates with the Internet 330 which in turn is connected to a server 332 which allows remote configuration of the device via known communication links 334 and 336. For example, techniques are known to provide over the air provisioning of software code that is stored on the device and executed by the one or more processors. However, instead of provisioning software, configuration information may be remotely provided to allow post-package level control of the one or more functional blocks as further described below.

FIG. 4 is a cross-sectional view of the die shown in FIG. 3, by way of example, where the die includes a substrate 400 on top of which is formed a functional block layer 402 (made of multiple layers or semiconductor material that include active circuit devices such as CMOS transistors) that in this example includes a plurality of functional blocks that are shown to be functional blocks 302 and 304. The functional block layer includes active semiconductor devices that are capable of electrically controlling electron flow, such as but not limited to, bipolar or field effect transistors (FET), semiconductor controlled rectifiers (SCR), or triode for alternating current (TRIAC), to name a few. It will be recognized that layer 402 is the functional circuit layer, and it contains both transistors and metal layers typically found in IC's. The PVRMs do not necessarily have to sit above the metal layers too. The PVRM layers could sit above the normal metal layers or below the normal metal layers (although this may not be optimal), or even share some layers with the metal layers. In other words, the PVRM can sit above the transistors of a functional block, but do not necessarily have to sit above all metal layers. The processors or other functional blocks may also include passive devices that are incapable of controlling current by means of another electrical signal, such as but not limited to resistors, capacitors, inductors, transformers, transmission lines, or any other suitable passive device. In a preferred example, the functional blocks, such as a processor, include active CMOS circuits and passive devices (e.g. metal interconnections) constructed in the surface of a thin single-crystal silicon substrate. As noted above, the processor, if employed may include at least one of a CPU having one or multiple cores, a discrete or integrated GPU, an APU, a GPGPU, and any other suitable logic.

The passive variable resistance memory controller 206 which may contain active components such as memory cell line drivers and bit drivers and row and column access read and write circuitry, as known in the art may be formed in the functional block layer 402 using conventional fabrication techniques. A conductive electrode layer 404 (e.g. metal layer) is formed on top of the functional block layer 402. The on-die distributed programmable passive variable resistance memory array 317 is formed in layers above the functional block layer and is formed above in this example, the electrode layer 404. The on-die distributed programmable passive variable resistance memory array 317 includes each of the respective distributed sub-portions 310, 312, 314 and 316. In this example, sub-portion 310 and 312 are illustrated. The corresponding sub-portion of the on-die distributed programmable passive variable resistance memory is fabricated in layers above each respective plurality of functional blocks. For example as shown, functional block 304 has its corresponding sub-portion of the distributed passive variable resistance memory array 312 fabricated in layers above it. Similarly, 310 lies above functional block 302.

The on-die distributed programmable passive variable resistance memory array 317 forms a layer (made up of multiple layers within) above the plurality of functional blocks such that a corresponding sub-portion of the on-die distributed passive resistance memory is fabricating layers above each respective plurality of functional blocks. The electrode layer interconnects the functional block layer with the on-die distributed programmable passive variable resistance memory array layer above the plurality of functional blocks.

The electrode layer 404 may be formed using any suitable metal or semiconductor materials such as but not limited to platinum, copper, gold, aluminum, titanium, iridium, iridium oxide, ruthenium, or silver, by thin-film deposition techniques such as CVD, thermal evaporation, sputtering, MBE, or electroplating. The on die passive variable resistance memory array defined, in the example above by sub-portions 310, 312,314 and 316 may be formed by thin-film deposition techniques such as CVD, thermal evaporation, sputtering, MBE, electroplating, spin-coating, or any other suitable techniques. The material of the passive variable resistance memory cell array may be any suitable variable resistance material that is capable of storing state by resistance. Depending on the specific type of passive variable resistance memory, the material of the passive variable resistance memory layer may include, for example, one or more thin-film oxides (e.g., TiO₂, SiO₂, NiO, CeO₂, VO₂, V₂O₅, ^{Nb}₂O₅, Ti₂O₃, WO₃, Ta₂O₅, ZrO₂, IZO, ITO, etc.) for memristors, chalcogenide for phase-change memory, and ferromagnetic materials (e.g., CoFeB incorporated in MgO) for magnetoresistive memory.

It is known in the art that memory may be implemented by an array of memory cells. Each memory cell of the array includes a memory region as a place to store state, which represents one bit of information. In order to access each memory cell, the array of memory is organized by rows and columns, and the intersection point of each row-column pair is a memory region. The rows are also called word lines, whereas the columns are named bit lines.

In this example embodiment, each passive variable resistance memory cell (e.g. one bit) may be a memristor of any suitable design. The passive variable resistance memory cell array 210 in this example embodiment, is implemented as a memory layer of memristor passive variable-resistive memory cells (e.g. each 1 bit) and may be of any suitable design. Since a memristor includes a memory region (e.g., a layer of TiO₂) between two metal contacts (e.g., platinum wires), memristors could be accessed in a cross point array style (i.e., crossed-wire pairs) with alternating current to non-destructively read out the resistance of each memory cell. A cross point array is an array of memory regions that can connect each wire in one set of parallel wires to every member of a second set of parallel wires that intersects the first set (usually the two sets of wires are perpendicular to each other, but this is not a necessary condition). The memristor disclosed herein may be fabricated using a wide range of material deposition and processing techniques. One example is disclosed in corresponding U.S. Patent Application Publication No. 2008/0090337, having a title “ELECTRICALLY ACTUATED SWITCH”, which is incorporated herein by reference.

In this example, first, a lower electrode is fabricated above the actual memory cell array 208 using conventional techniques such as photolithography or electron beam lithography, or by more advanced techniques, such as imprint lithography. This may be, for example, a bottom wire of a crossed-wire pair. The material of the lower electrode may be either metal or semiconductor material, preferably, platinum.

In this example, the next component of the memristor to be fabricated is the non-covalent interface layer, and may be omitted if greater mechanical strength is required, at the expense of slower switching at higher applied voltages. In this case, a layer of some inert material is deposited. This could be a molecular monolayer formed by a Langmuir-Blodgett (LB) process or it could be a self-assembled monolayer (SAM). In general, this interface layer may form only weak van der Waals-type bonds to the lower electrode and a primary layer of the memory region. Alternatively, this interface layer may be a thin layer of ice deposited onto a cooled substrate. The material to form the ice may be an inert gas such as argon, or it could be a species such as CO₂. In this case, the ice is a sacrificial layer that prevents strong chemical bonding between the lower electrode and the primary layer, and is lost from the system by heating the substrate later in the processing sequence to sublime the ice away. One skilled in this art can easily conceive of other ways to form weakly bonded interfaces between the lower electrode and the primary layer.

Next, the material for the primary layer is deposited. This can be done by a wide variety of conventional physical and chemical techniques, including evaporation from a Knudsen cell, electron beam evaporation from a crucible, sputtering from a target, or various forms of chemical vapor or beam growth from reactive precursors. The film may be in the range from 1 to 30 nanometers (nm) thick, and it may be grown to be free of dopants. Depending on the thickness of the primary layer, it may be nanocrystalline, nanoporous or amorphous in order to increase the speed with which ions can drift in the material to achieve doping by ion injection or undoping by ion ejection from the primary layer. Appropriate growth conditions, such as deposition speed and substrate temperature, may be chosen to achieve the chemical composition and local atomic structure desired for this initially insulating or low conductivity primary layer.

The next layer is a dopant source layer, or a secondary layer, for the primary layer, which may also be deposited by any of the techniques mentioned above. This material is chosen to provide the appropriate doping species for the primary layer. This secondary layer is chosen to be chemically compatible with the primary layer, e.g., the two materials should not react chemically and irreversibly with each other to form a third material. One example of a pair of materials that can be used as the primary and secondary layers is TiO₂ and TiO₂₋ₓ, respectively. TiO₂ is a semiconductor with an approximately 3.2 eV bandgap. It is also a weak ionic conductor. A thin film of TiO₂ creates the tunnel barrier, and the TiO₂₋ₓ forms an ideal source of oxygen vacancies to dope the TiO₂ and make it conductive.

Finally, the upper electrode in the passive variable resistance memory layer is fabricated on top of the secondary layer in a manner similar to which the lower electrode was created. This may be, for example, a top wire of a crossed-wire pair. The material of the upper electrode may be either metal or semiconductor material, preferably, platinum. If the memory cell is in a cross point array style, an etching process may be necessary to remove the deposited memory region material that is not under the top wires in order to isolate the memory cell. It is understood, however, that any other suitable material deposition and processing techniques may be used to fabricate memristors for the passive variable-resistive memory. It will also be recognized that any other suitable passive variable resistance technology may be employed as mentioned above or that the order of operation may be rearranged in any suitable manner. It will be recognized that programming voltages for the PVRM could be any suitable levels depending upon the application.

It will be understood that PVRM is a term used to describe any memory technology that stores state in the form of resistance instead of charge. That is, PVRM technologies use the resistance of a cell to store the state of a bit, in contrast to charge-based memory technologies that use electric charge to store the state of a bit. PVRM is referred to as being passive due to the fact that it does not require any active semiconductor devices, such as transistors, to act as switches. These types of memory are said to be “non-volatile” due to the fact that they retain state information following a power loss or power cycle. Passive variable resistive memory is also known as resistive non-volatile random access memory (RNVRAM or RRAM).

Examples of PVRM include, but are not limited to, Ferroelectric RAM (FeRAM), Magnetoresistive RAM (MRAM), Memristors, Phase Change Memory (PCM), and Spin-Torque Transfer MRAM (STT-MRAM). While any of these technologies may be suitable for use in the IC 102 disclosed herein, PCM, memristors, and STT-MRAM are contemplated as providing an especially nice fit and are therefore discussed below in additional detail.

Phase change memory (PCM) is a PVRM technology that relies on the properties of a phase change material, generally chalcogenides, to store state. Writes are performed by injecting current into the storage device, thermally heating the phase change material. An abrupt shutoff of current causes the material to freeze in an amorphous state, which has high resistivity, whereas a slow, gradual reduction in current results in the formation of crystals in the material. The crystalline state has lower resistance than the amorphous state; thus a value of 1 or 0 corresponds to the resistivity of a cell. Varied current reduction slopes can produce in-between states, allowing for potential multi-level cells. A PCM storage element consists of a heating resistor and chalcogenide between electrodes, while a PCM cell is comprised of the storage element and an access transistor. Access transistors may be in the silicon layer (e.g., active layers), however it will be recognized that they may not be necessary depending upon the technology used or they can be located at any suitable location.

Memristors are commonly referred to as the “fourth circuit element,” the other three being the resistor, the capacitor, and the inductor. A memristor is essentially a two-terminal variable resistor, with resistance dependent upon the amount of charge that passed between the terminals. Thus, a memristor's resistance varies with the amount of current going through it, and that resistance is remembered even when the current flow is stopped.

Spin-Torque Transfer Magnetoresistive RAM (STT-MRAM) is a second-generation version of MRAM, the original of which was deemed “prototypical” by the International Technology Roadmap for Semiconductors (ITRS). MRAM stores information in the form of a magnetic tunnel junction (MTJ), which separates two ferromagnetic materials with a layer of thin insulating material. The storage value changes when one layer switches to align with or oppose the direction of its counterpart layer, which then affects the junction's resistance. Original MRAM required an adequate magnetic field in order to induce this change. This was both difficult and inefficient, resulting in impractically high write energy. STT-MRAM uses spin-polarized current to reverse polarity without needing an external magnetic field. Thus, the STT technique reduces write energy as well as eliminating the difficult aspect of producing reliable and adequately strengthen magnetic fields. However, STT-MRAM, like PCM, requires an access transistor and thus its cell size scaling depends on transistor scaling.

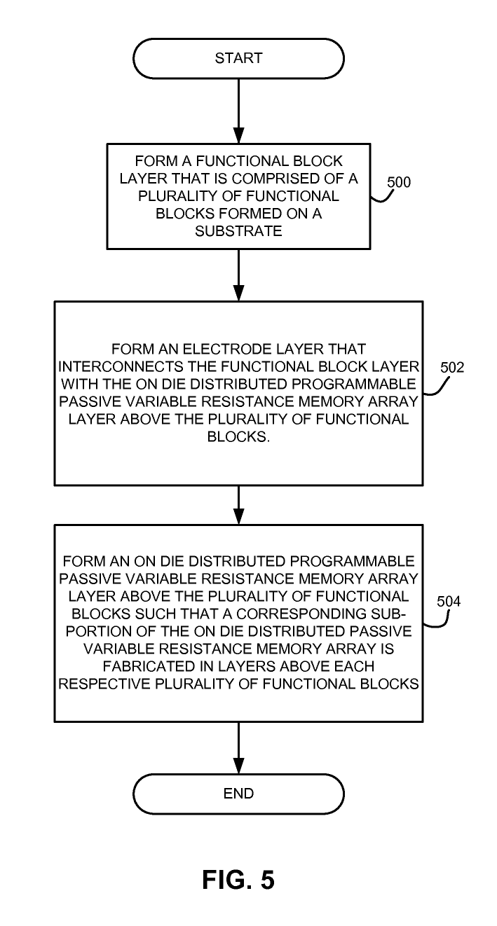

FIG. 5 illustrates one example of a method of making an integrated circuit such as that shown in FIG. 4, which includes forming a functional block layer 402 that includes a plurality of functional blocks 302, 304, and 306 for example that are formed on a substrate 400. This can be done using conventional circuit fabrication techniques and in this example, the functional layer includes active components such as transistors as noted above. By way of example, functional blocks may include processor cores and any other suitable functional operations of the application specific integrated circuit, CPU, GPU or any other suitable integrated circuit. As shown in block 502, the method includes forming an electrode layer 404 on top of the functional layer 402. The electrode layer may be, for example, a metal connection layer as described above. It will be recognized that the term “layer” as used herein can include multiple layers within the general layers identified in FIG. 4. The electrode layer 404 interconnects the functional block 402 with the on-die distributed programmable passive variable resistance memory arrays 317 shown in passive variable memory layer 406. The passive variable resistance memory array layer is located in layers above the plurality of functional blocks and in this example, are actually above the electrode layer 404 which is interposed between the active functional block layer and the passive variable resistance memory array layer 406. This layer may be made in a manner noted above using conventional techniques. However, the PVRM may be located below this layer but above the functional blocks (active transistor layers) or among the normal metal layers if desired.

The method also includes, as shown in block 504, forming an on-die distributed programmable passive variable resistance memory array layer 406 above the plurality of functional blocks 302 and 304 such that a corresponding sub-portion 310, 312, for example, of the on-die distributed programmable passive variable resistance memory array is fabricated in layers above each respective plurality of functional blocks. As shown, the passive variable resistance memory 310 or 312 that stores configuration information overlaps the respective functional blocks for which they store information and may overlap other functional blocks depending upon the amount of memory required for a given functional block. The metal electrode layer 404 is suitably configured to interconnect the sub-portions of the PVRM with corresponding functional blocks which can help minimize distance between the memory cells to provide faster reconfiguration in locating the fuse type or reprogrammable configuration information stores in a stacked manner can reduce real estate on a die. Forming of the on-die distributed programmable passive variable resistance memory array layer is set forth above. The method for making the integrated circuit may also include forming an electrode layer between the functional block layer and the on-die distributed programmable passive variable resistance memory array layer.

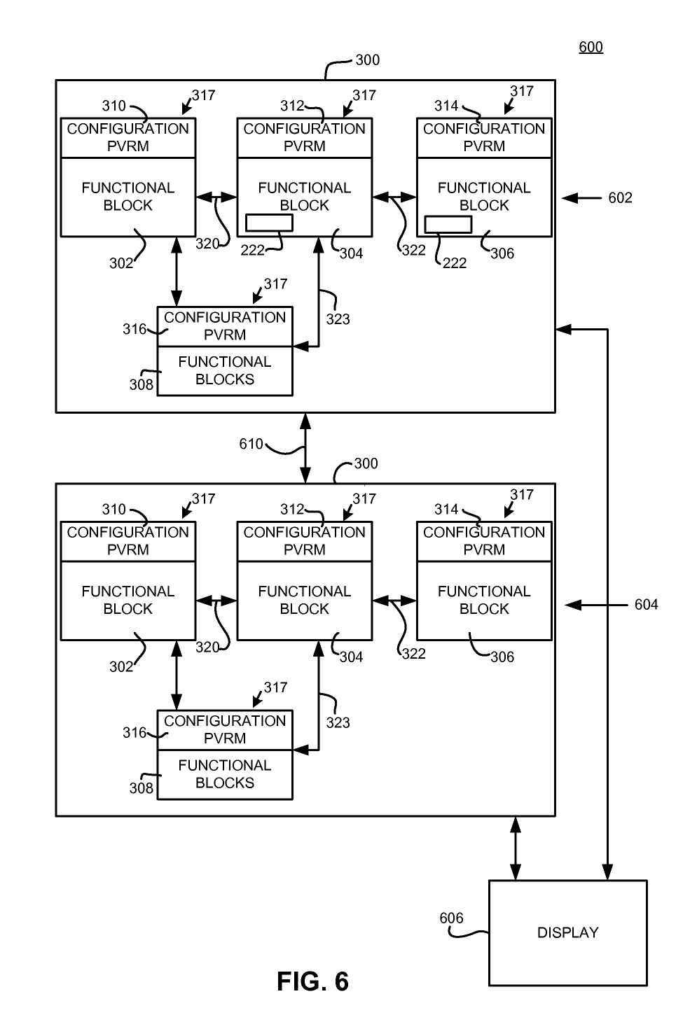

Referring to FIG. 6, a device 600, such as a smart phone, computer, server, printer, or any other suitable device employs a plurality of integrated circuit packages 602 and 604 wherein each package includes the structure, for example, as shown in FIG. 3. In this example, the functional blocks are shown as being processor cores. Other known circuitry is not shown for purposes of simplicity. A display 606 may be coupled to the plurality of integrated circuit packages 602 and 604 to present images that are produced by one or more of the integrated circuit packages 602 or 604 as known in the art. A communication link 610 allows communication of information between the two integrated circuits as known in the art.

The control logic may be separate from or integrated in the processors as noted above. The control logic 222 depending upon a particular device or desired operation, may for example, control the operating speed of one or more functional blocks such as if the functional blocks for each processors, the control logic may select from a register, a differing clock speed for each respective functional block as controlled, for example, by any suitable control mechanism such as through the operating system, application, driver or any other suitable technique as known in the art. The control logic may also control selection of a redundant functional block where, for example, as shown in FIG. 3 one of the functional blocks may be selected by control logic 222 to be non-functional through a chip level control that prevents, for example, putting the processor in a sleep mode or otherwise operates a switch to allow power to be selectively applied in the event that another of the functional blocks is determined to be faulty, another functional block can be suitably turned on under control the operating system or application or through any suitable hardware mechanism. In addition it will be recognized that real time testing in the background as known in the art may be performed or a timer may be used to anticipate when a functional block may be at the end of its life. At such time an unused functional block which is redundant on the integrated circuit may be activated.

The control logic 222 may also control supply voltage level of a functional block through known voltage supply control circuitry (not shown) depending upon whether or not, for example, a sleep mode of the device has been detected or for any other suitable purpose.

In another example, the control logic is operative to control the security level of the functional block by controlling, for example, a cryptographic engine which allows higher level of security to be carried out by one functional block compared with another functional block through a register setting that sets the level of security for the encryption engine if desired. The control logic may also activate or deactivate functional blocks based on a pay for performance criteria that may be, for example, activated through the remote performance update server 332. By way of example, if a user initially purchases the integrated circuit but only wishes to use 2 or 4 processors, for example, the purchaser may charged a lower price. However, if the user wishes to take advantage of additional processing power, the user may pay for this performance through any known online purchase technique through the remote performance update server 332. The remote performance update server 332 may then download control information for the control logic 222 to activate additional functional blocks. In a similar manner, the control logic may also control the use of different functional blocks in the integrated circuit for different end users. For example, if the functional blocks are processor cores and for example, the integrated circuits include 8 cores, 2 may be used for one end user and the remaining 6 may be used for another end user. Other configuration operations may be recognized by those of ordinary skill in the art.

Also, integrated circuit design systems (e.g., work stations) are known that create wafers with integrated circuits based on executable instructions stored on a computer readable medium such as but not limited to CDROM, RAM, other forms of ROM, hard drives, distributed memory, etc. The instructions may be represented by any suitable language such as but not limited to hardware descriptor language (HDL), Verilog or other suitable language. As such, the logic and circuits described herein may also be produced as integrated circuits by such systems using the non-transitory computer readable medium with instructions stored therein. For example, an integrated circuit with the aforedescribed logic and structure may be created using such integrated circuit fabrication systems. The non-transitory computer readable medium stores instructions executable by one or more integrated circuit design systems that causes the one or more integrated circuit design systems to fabricate an integrated circuit. The designed integrated circuit includes an integrated circuit comprising a plurality of functional blocks, an on-die distributed programmable passive variable resistance memory array configured to provide configuration information for each of the plurality of functional blocks, wherein a corresponding sub-portion of the on-die distributed passive variable resistance memory array is fabricated in layers above each respective plurality of functional blocks, passive variable resistance memory (PVRM) memory array, positioned above (e.g., over or on top of) the respective functional blocks. The fabricated integrated circuit may also include the other aspects described herein.

Among other advantages, employing a distributed programmable passive variable resistance memory array wherein sub-portions are located in layers above each respective plurality of functional blocks can result in a smaller integrated circuit design and can allow a larger number of fuse type operations or other hardware configuration operations to be facilitated using an improved design.

The above detailed description of the invention and the examples described therein have been presented for the purposes of illustration and description only and not by limitation. It is therefore contemplated that the present invention cover any and all modifications, variations or equivalents that fall within the spirit and scope of the basic underlying principles disclosed above and claimed herein.

What is claimed is:

1. An integrated circuit comprising:
a plurality of functional blocks; and
an on-die distributed programmable passive variable resistance memory array configured to provide configuration information for each of the plurality of functional blocks.

2. The integrated circuit of claim 1 wherein a corresponding sub-portion of the on-die distributed passive variable resistance memory array is fabricated in layers above each respective plurality of functional blocks.

3. The integrated circuit of claim 1 wherein the distributed passive variable resistance memory array is configured to provide both prepackage and post-package level configuration information for the plurality of functional blocks.

4. The integrated circuit of claim 1 comprising program logic operative to program the configuration information in the on-die distributed programmable passive variable resistance memory array during prepackage operation of the plurality of functional blocks.

5. The integrated circuit of claim 1 comprising control logic operatively responsive to the configuration information to at least one of: control operating speed of one or more functional blocks, control selection of a redundant functional block to replace another functional block, control a supply voltage level for a functional block, control a security level of at least one functional block, control selection of different combinations of functional blocks based on pay for performance criteria, control use of different functional blocks in the integrated circuit for different end users.

6. The integrated circuit of claim 2 comprising program logic that is operative to program the on-die distributed programmable passive variable resistance memory array.

7. A device comprising:
a plurality of integrated circuit packages each comprising:
a plurality of functional blocks;
an on-die distributed programmable passive variable resistance memory array configured to provide configuration information for each of the plurality of functional blocks; and
control logic, operatively coupled to the plurality of integrated circuit packages, and operative to program new configuration information in each of the respective on-die distributed programmable passive variable resistance memory arrays on each of the plurality of integrated circuit packages to change hardware configuration settings in response to a change in performance condition.

8. The device of claim 7 wherein a corresponding sub-portion of the on-die distributed passive variable resistance memory array in each of the plurality of integrated circuit packages is fabricated in layers above each respective plurality of functional blocks.

9. The device of claim 8 wherein the control logic controls at least one of: an operating speed of one or functional blocks, selection of a redundant functional block to replace another functional block, a supply voltage level for a functional block, a security level of at least one functional block, selection of different combinations of functional blocks based on pay for performance criteria, and use of different functional blocks in the integrated circuit for different end users.

10. An integrated circuit made by a process comprising:
forming a functional block layer that is comprised of a plurality of functional blocks formed on a substrate;
forming an on-die distributed programmable passive variable resistance memory array layer above the plurality of functional blocks such that a corresponding sub-portion of the on-die distributed passive variable resistance memory array is fabricated in layers above each respective plurality of functional blocks; and
forming an electrode layer that interconnects the functional block layer with the on-die distributed programmable passive variable resistance memory array layer above the plurality of functional blocks.

11. The integrated circuit of claim 10 wherein forming the electrode layer comprises forming the electrode layer between the functional block layer and the on-die distributed programmable passive variable resistance memory array layer.

12. A method for making an integrated circuit comprising:
forming a functional block layer that is comprised of a plurality of functional blocks formed on a substrate;
forming an on-die distributed programmable passive variable resistance memory array layer above the plurality of functional blocks such that a corresponding sub-portion of the on-die distributed passive variable resistance memory array is fabricated in layers above each respective plurality of functional blocks; and
forming an electrode layer that interconnects the functional block layer with the on-die distributed programmable passive variable resistance memory array layer above the plurality of functional blocks.

13. The method of claim 12 wherein forming the electrode layer comprises forming the electrode layer between the functional block layer and the on-die distributed programmable passive variable resistance memory array layer.

14. An integrated circuit comprising:
a plurality of processors; and
an on-die distributed programmable passive variable resistance memory array configured to provide configuration information for each of the plurality of processors wherein a corresponding sub-portion of the on-die distributed passive variable resistance memory array is fabricated in layers above each respective plurality of processors.

15. The integrated circuit of claim 14 comprising program logic operative to program the configuration information in the on-die distributed programmable passive variable resistance memory array during both prepackage operation and post package operation to provide both prepackage and post-package level configuration information for the plurality of processors.

16. The integrated circuit of claim 15 comprising control logic in each of the plurality of processors that is operatively responsive to the configuration information to at least one of:
control operating speed of one or functional blocks, control selection of a redundant functional block to replace another functional block, control a supply voltage level for a functional block, control a security level of at least one functional block, control selection of different combinations of functional blocks based on pay for performance criteria, control use of different functional blocks in the integrated circuit for different end users.

17. The integrated circuit of claim 16 wherein the program logic programs the PVRM array.

18. A non-transitory computer readable storage medium comprising:
executable instructions that are executable by one or more integrated circuit design systems that causes the one or more integrated circuit design systems to fabricate an integrated circuit that comprises:
a plurality of functional blocks; and
an on-die distributed programmable passive variable resistance memory array configured to provide configuration information for each of the plurality of functional blocks.

19. The computer readable medium of claim 18 comprising executable instructions that when executed by one or more integrated circuit fabrication systems causes the integrated circuit fabrication system to produce an integrated circuit that comprises the on-die distributed programmable passive variable resistance memory array to include corresponding sub-portions that are fabricated in layers above each respective plurality of functional blocks.

20. The computer readable medium of claim 18 comprising:
executable instructions that when executed by one or more integrated circuit fabrication systems causes the integrated circuit fabrication system to produce an integrated circuit that comprises the on-die distributed programmable passive variable resistance memory array to include corresponding sub-portions that are fabricated in layers above each respective plurality of functional blocks; and
program logic that is operative to program the on-die distributed programmable passive variable resistance memory array using a normal operating voltage of the integrated circuit.
